(19) United States
(12) Patent Application Publication
(10) Pub. No.: US 2009/0325081 A1
(43) Pub. Date: Dec. 31, 2009

(54) EXPOSURE MASK AND MANUFACTURING METHOD OF A SEMICONDUCTOR USING THE SAME

(75) Inventors: Won Kwang Ma, Icheon-si (KR); Tae Seung Eom, Seongnam-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/266,439

(22) Filed: Nov. 6, 2008

(30) Foreign Application Priority Data
Jun. 27, 2008 (KR) 10-2008-0061888

(51) Int. Cl. G03F 1/00; G03F 7/20

(52) U.S. Cl. 430/5; 430/313

(57) ABSTRACT

An exposure mask for EUV comprises an absorber formed over a mask substrate and a reflecting pattern formed over the absorber. The exposure mask for EUV prevents re-absorption of light reflected from a reflector by an absorber pattern to prevent a shadowing effect. As a result, a photoresist pattern reflects the pattern formed in the exposure mask without distortion, thereby obtaining a desired pattern.

### CROSS-REFERENCES TO RELATED APPLICATIONS

Priority is claimed to Korean patent application number 10-2008-0061888, filed on Jun. 27, 2008, which is incorporated by reference in its entirety.

### BACKGROUND OF THE INVENTION

The present invention generally relates to an exposure mask and a method of manufacturing a semiconductor device using the same, and more specifically, to a exposure mask for extreme ultraviolet radiation (EUV) applied to a system for reflecting and exposing light and a method of manufacturing a semiconductor device using the same.

Various exposure techniques have been developed as the design rule of semiconductor devices is reduced. One of these exposure techniques is a method using extreme ultraviolet radiation (EUV).

The exposure technique using EUV does not facilitate a patterning process using a conventional system lens because it uses high energy light having a wavelength band of 13.5 nm.

That is, since the exposure light source has a high energy of a short wavelength band, light from the light source is absorbed in an absorber when it is projected into an exposure mask and a lens. As a result, it is necessary to introduce a reflection-type system.

The reflection-type system is not similar to a conventional system for forming a pattern using light penetrating the exposure mask. The reflection-type system is a patterning system for reflecting light through a reflecting device such as a reflecting mirror.

Since the exposure technique using EUV adapts the system for reflecting light, light from a light source is projected into the exposure mask not vertically but at a given incidence angle. The slanted light is reflected by the reflection layer of the exposure mask or absorbed in the absorber of the exposure mask.

FIGS. 1a to 1c are diagrams illustrating a conventional method of manufacturing an exposure mask.

As shown in FIG. 1a, a reflector 12 for reflecting light, a buffer layer 14 and an absorber 16 for absorbing light are formed over a mask substrate 10.

As shown in FIG. 1b, a mask is patterned in order to obtain a desired shape over a wafer. A photoresist film is coated over the absorber 16, and the photoresist film is patterned to have a desired shape, thereby obtaining a photoresist pattern 18.

As shown in FIG. 1c, the absorber 16 and the buffer layer 14 are etched using the photoresist pattern 18 as an etch mask, thereby obtaining a buffer pattern 20 and an absorber pattern 22.

FIG. 2 is a diagram illustrating an exposing process using a conventional exposure mask.

As shown in FIG. 2, when a patterning process is performed with an exposure mask including a mask pattern formed by a conventional mask forming method, light from a light source is projected into the exposure mask with an incidence angle, so that light is also reflected at a slant with a given angle.

That is, of the light projected into the exposure mask, the light reflected from the reflector 12 as shown by ‘A’ is exposed over the wafer to pattern the photoresist film coated over the wafer, and the light absorbed in the absorber pattern 20 as shown by ‘B’ does not reach the photoresist film coated over the wafer and therefore does not pattern the photoresist film.

The light as shown by ‘C’ is reflected with a given angle from the reflector 12, and penetrates the absorber pattern 22. In other words, the light is not reflected but absorbed to generate an unexposed portion of the wafer.

As a result, the unexposed portion affects the shape of the pattern to transform the pattern, which is called a shadowing effect.

The shadowing effect degrades a contrast of the pattern to distort the pattern when light is reflected on a mask to pattern a film.

### BRIEF SUMMARY OF THE INVENTION

Various embodiments of the present invention are directed at providing an exposure mask and a method of manufacturing a semiconductor device, thereby preventing a shadowing effect generated in an exposure process using EUV.

According to an embodiment of the present invention, an exposure mask comprises: an absorber formed over a mask substrate; and a reflecting pattern formed over the absorber.

The exposure mask may further comprise a buffer pattern between the absorber and the reflecting pattern.

The absorber may include TaN, TaON, Ta₉N, Ta₈ON, TaBON or Ta₇BON.

The reflecting pattern has a multi-layered structure including different materials.

The reflecting pattern includes molybdenum (Mo) and silicon (Si).

The reflecting pattern includes between 40 and 60 layers.

The exposure mask is used for EUV.

According to an embodiment of the present invention, a method of manufacturing a semiconductor device comprises: coating a photoresist film over a semiconductor substrate including an underlying layer; performing an exposing process using EUV on the photoresist film with the above-described exposure mask for EUV; performing a developing process on the photoresist film to form a photoresist pattern; and etching the underlying layer using the photoresist pattern as an etch mask.

According to an embodiment of the present invention, a method of forming an expose mask comprises: forming an absorber over a mask substrate; and forming a reflecting pattern over the absorber.

The forming-a-reflecting-pattern includes: forming a reflector over the absorber; forming a photoresist pattern over the reflector; and etching the absorber using the photoresist pattern as an etch mask.

The method of forming an expose mask may further include forming a buffer pattern between the absorber and the reflecting pattern.

The absorber may include TaN, TaON, Ta₉N, Ta₈ON, TaBON or Ta₇BON.

The reflecting pattern has a multi-layered structure including different materials.

The reflecting pattern includes Mo and Si.

The reflecting pattern includes between 40 and 60 layers.

The exposure mask is used for EUV.

### BRIEF DESCRIPTION OF THE DRAWINGS

FIGS. 1a to 1c are diagrams illustrating a conventional method of manufacturing an exposure mask.

FIG. 2 is a diagram illustrating an exposing process using a conventional exposure mask.

FIGS. 3a to 3c are diagrams illustrating a method of manufacturing an exposure mask according to an embodiment of the present invention.

FIGS. 4a to 4c are diagrams illustrating a method of manufacturing a semiconductor device using the exposure mask according to an embodiment of the present invention.

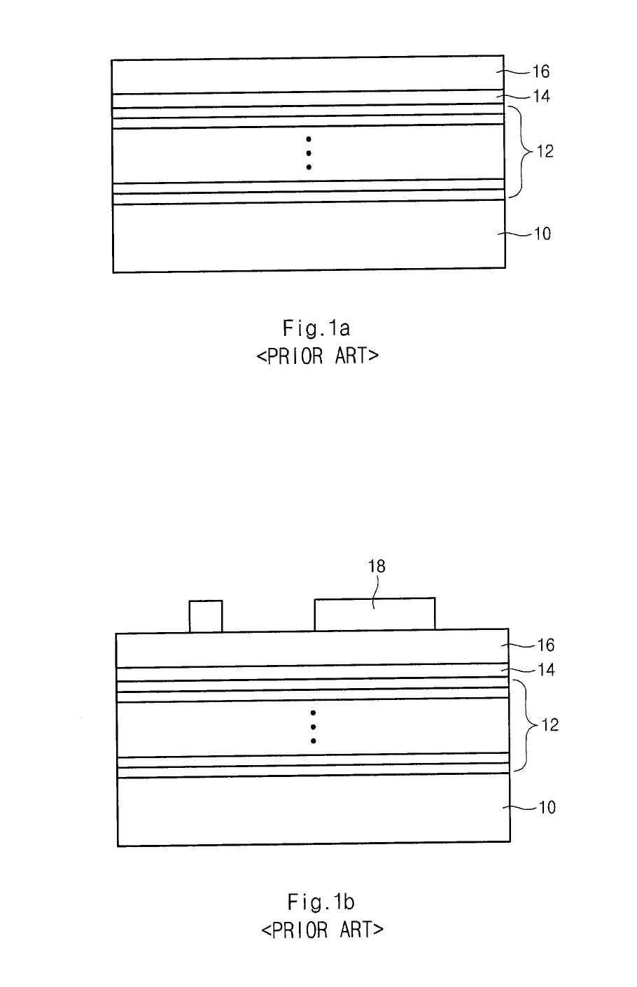

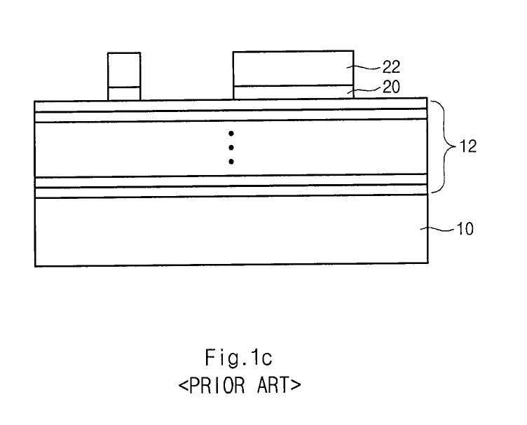

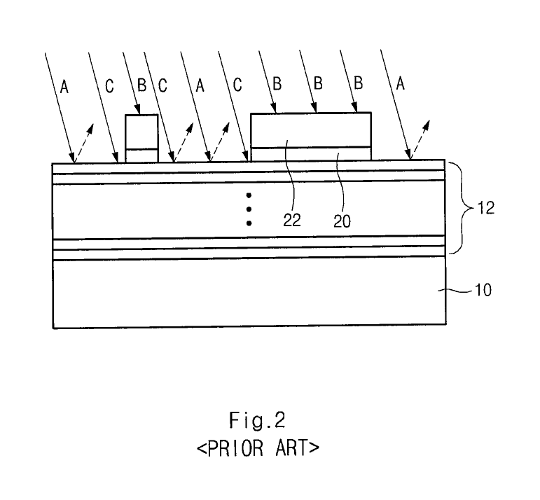

### DESCRIPTION OF EMBODIMENTS

The present invention will be described in detail with reference to the drawings.

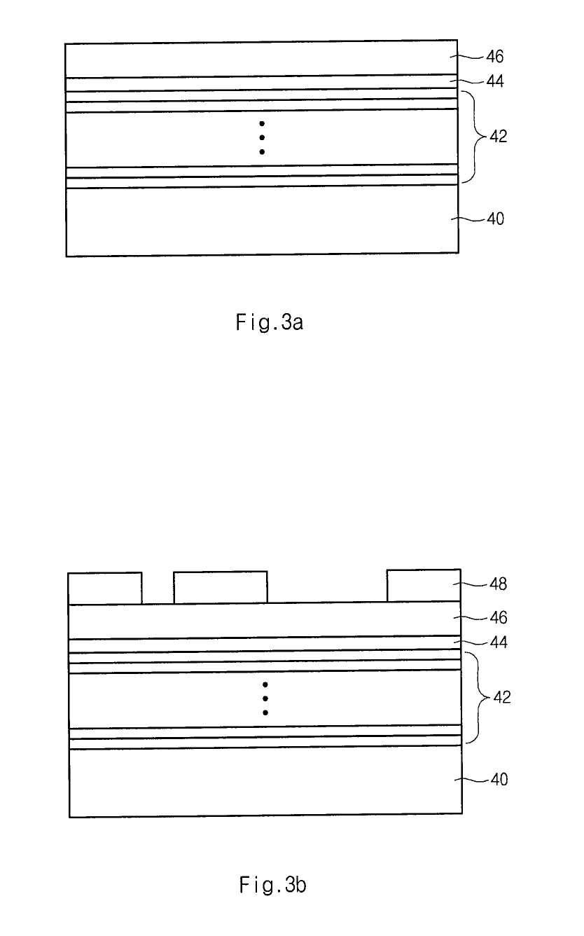

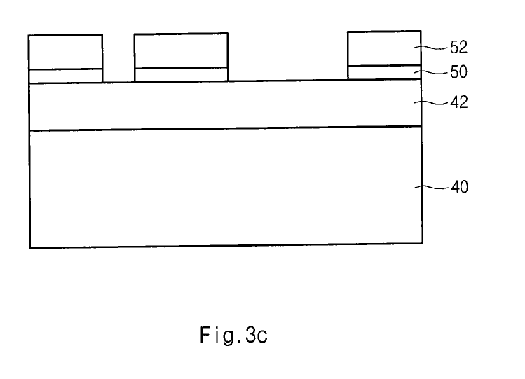

An exposure mask according to an embodiment of the present invention, as shown in FIG. 3c, comprises an absorber 42, a buffer pattern 50 used as a mask pattern formed over the absorber 42, and a reflector pattern 52, all of which are formed over a mask substrate 40.

In the exposure mask, a reflecting system is applied rather than a patterning system. As a result, a photoresist film coated over the semiconductor substrate is patterned using light reflected from the reflector pattern 52.

FIGS. 3a to 3c are diagrams illustrating a method of manufacturing an exposure mask according to an embodiment of the present invention.

Referring to FIG. 3a, the absorber 42 for absorbing light, a buffer layer 44, and a reflector 46 for reflecting light are sequentially formed over the mask substrate 40.

The reflector 46 has a multi-layer deposition structure including material for reflecting light optimally.

The reflector 46 has a deposition structure including Mo and Si to be between 40 and 60 layers, and is not limited herein. Any material for reflecting light optimally can be used, and the number of deposited layers can be changed depending on reflectivity.

The absorber 42 may include TaN, TaON, Ta₉N, Ta₈ON, TaBN, TaBON or Ta₇BON, and is not limited herein.

As shown in FIG. 3b, a mask pattern is formed so that the mask pattern may be patterned to have a desired shape over the wafer using a mask. A photoresist film is coated over the reflector 46, and patterned to have a desired shape, thereby obtaining a photoresist pattern 48.

As shown in FIG. 3c, the reflector 46 and the buffer layer 44 are etched using the photoresist pattern 48 as an etch mask, thereby obtaining a buffer pattern 50 and a reflector pattern 52 which are mask patterns.

In this way, the absorber 42 is first formed over the mask substrate 40, so that the light reflected from the reflector of the exposure mask is not re-absorbed by the absorber pattern, thereby preventing a shadowing effect.

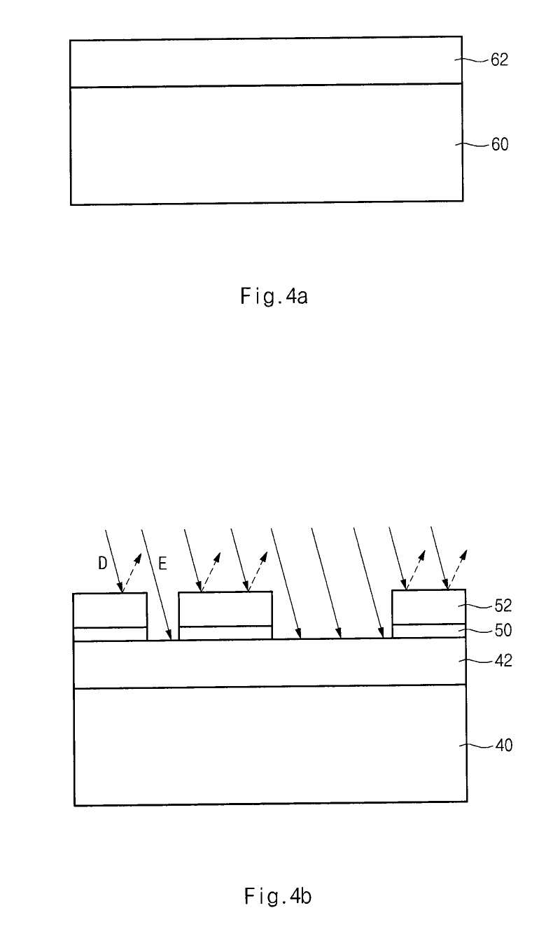

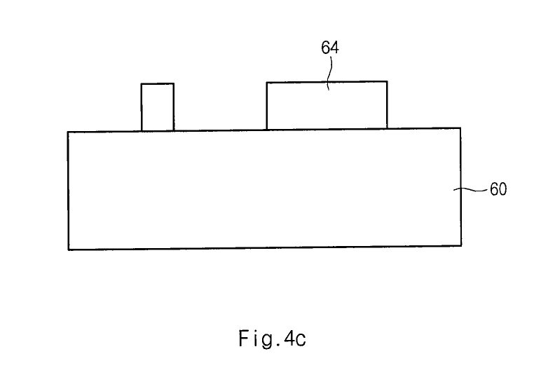

FIGS. 4a to 4c are diagrams illustrating a method of manufacturing a semiconductor device using the exposure mask according to an embodiment of the present invention.

As shown in FIG. 4a, a photoresist film 62 is coated over a semiconductor substrate 60 including an underlying layer (not shown).

As shown in FIG. 4b, an exposure process is performed with the above-described exposure mask for EUV according to the embodiment of the present invention.

Light from a light source is projected into the exposure mask not vertically but at a slant with an incidence angle, so that light is reflected by the exposure mask at a slant.

Of the light projected into the exposure mask, light ‘D’ projected into the reflector pattern 52 as a mask pattern is reflected from the reflector pattern 52, and is exposed over the wafer. As a result, the photoresist film 62 coated over the semiconductor substrate 60 is exposed. Light ‘E’ projected into the absorber 42 is absorbed by the absorber 42, so that it is not exposed in the photoresist film 62.

As shown in FIG. 4c, a developing process is performed on the photoresist film 62 to form a photoresist pattern 64.

The underlying layer (not shown) is etched with the photoresist pattern 64 to manufacture a semiconductor device.

As described above, the exposure mask for EUV according to an embodiment of the present invention prevents re-absorption of light reflected from the reflector by the absorber pattern to prevent the shadowing effect. As a result, the photoresist pattern 64 reflects the pattern formed in the exposure mask without distortion, thereby obtaining a desired pattern.

The method of manufacturing a semiconductor device using the exposure mask according to an embodiment of the present invention does not require optical proximity correction in consideration of the pattern size in the exposure process using EUV, thereby preventing the shadowing effect without additional cost and process steps. Therefore, the pattern size resulting from transformation of the pattern may not be changed.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or a non volatile memory device. Other additions, subtractions, or modifications are obvious in view of the present disclosure and are intended to fall within the scope of the appended claims.

What is claimed is:

1. An exposure mask comprising:
an absorber formed over a mask substrate; and
a reflecting pattern formed over the absorber.

2. The exposure mask according to claim 1, further comprising a buffer pattern between the absorber and the reflecting pattern.

3. The exposure mask according to claim 1, wherein the absorber is selected from the group consisting of TaN, TaON, Ta₉N, Ta₈ON, TaBN, TaBON or Ta₇BON.

4. The exposure mask according to claim 1, wherein the reflecting pattern has a multi-layered structure including different materials.

5. The exposure mask according to claim 4, wherein the reflecting pattern includes molybdenum (Mo) and silicon (Si).

6. The exposure mask according to claim 4, wherein the reflecting pattern includes between 40 and 60 layers.

7. The exposure mask according to claim 1, wherein the exposure mask is used for extreme ultraviolet radiation (EUV).

8. A method of manufacturing a semiconductor device, the method comprising:
coating a photoresist film over a semiconductor substrate including an underlying layer;
performing an exposing process using EUV on the photoresist film with an exposure mask comprising:
an absorber formed over a mask substrate, and
a reflecting pattern formed over the absorber;
performing a developing process on the photoresist film to form a photoresist pattern; and
etching the underlying layer using the photoresist pattern as an etch mask.

9. A method for forming an exposure mask, the method comprising:
forming an absorber over a mask substrate; and
forming a reflecting pattern over the absorber.

10. The method according to claim 8, wherein the forming-a-reflecting-pattern step includes:
forming a reflector over the absorber;
forming a photoresist pattern over the reflector; and
etching the reflector using the photoresist pattern as an etch mask.

11. The method according to claim 9, further comprising forming a buffer layer between the absorber and the reflecting pattern.

12. The method according to claim 8, wherein the absorber is selected from the group consisting of TaN, TaON, Ta₉N, Ta₈ON, TaBN, TaBON or Ta₇BON.

13. The method according to claim 8, wherein the reflecting pattern has a multi-layered structure including different materials.

14. The method according to claim 8, wherein the reflecting pattern includes Mo and Si.

15. The method according to claim 8, wherein the reflecting pattern includes between 40 and 60 layers.

16. The method according to claim 8, wherein the exposure mask is used for EUV.
